(19) United States
(12) Patent Application Publication
(10) Pub. No.: US 2026/0195711 A1
(43) Pub. Date: Jul. 9, 2026

(54) METHOD AND SYSTEM FOR AUTOMATED DESIGN RECOMMENDATION USING A UNIFIED DESIGN FRAMEWORK

(71) Applicant: LTI Mindtree Ltd, Mumbai (IN)

(72) Inventors: Sujay Sen, Mumbai (IN); Nayna Raut, Mumbai (IN); Aniket Chakravorty, Mumbai (IN)

(21) Appl. No.: 19/188,041

(22) Filed: Apr. 24, 2025

(30) Foreign Application Priority Data
Jan. 6, 2025 (IN) 202521001162

(51) Int. Cl. G06Q 10/10; G06F 30/12; G06F 30/20

(52) U.S. Cl. CPC G06Q 10/103; G06F 30/12; G06F 30/20

(57) ABSTRACT

A method and system for automated design recommendation is disclosed. A unified design framework of the system includes a GUI that receives a user input. An integration controller coordinates data transfers between a plurality of design modules and enables automated data flow between consecutive modules to maintain design context across module transitions. The plurality of design modules such as, a research and strategy module utilizes a first LLM to evaluate product feasibility and strategy, a synthesis module utilizes a second LLM to generate synthetic user data based on the user input, an ideation module utilizes a third LLM to transform the synthetic user data into design requirements, a design module utilizes a fourth LLM to create design concepts based on the design requirements, and a go-to-market module utilizes a fifth LLM to generate market strategies based on the design concepts.

### FIELD

Various embodiments of the present disclosure generally relates to the field of computer-aided design and development. More particularly, the disclosure relates to a system and method for automated design recommendation using a unified design framework that employs large language models (LLMs) across multiple phases of the design lifecycle.

### BACKGROUND

The process of design recommendation traditionally follows a structured cycle aimed at creating user-centered solutions. It begins with research, which involves comprehensive desk and field studies to understand prevailing trends, user behaviors, and market gaps. Alongside this, primary research engages directly with potential users through methods such as interviews, surveys, and observational studies, providing deeper insights into their needs, preferences, and pain points. Following the research phase, synthesis is carried out to consolidate and interpret the data gathered. Once the synthesis identifies key areas of focus, the ideation stage begins. During this phase, creative brainstorming sessions are employed to develop a range of potential concepts that could address the identified challenges and capitalize on the opportunities.

The design process continues with several iterations of these concepts, refining them progressively to achieve a final, optimized design. Once the finalized concept is developed, it undergoes rigorous testing with real users. This usability testing ensures that the design is practical, intuitive, and capable of addressing user needs effectively.

Despite its structured nature, the traditional design cycle faces significant technical and operational challenges. The process is inherently time-intensive, demanding substantial computational and human resources at each stage. While the design cycle encompasses various phases from research to implementation, one of the most resource-intensive aspects is the research phase, where comprehensive data gathering and synthesis form critical foundations for subsequent stages. This time-intensive nature of data collection and analysis often creates bottlenecks in the design process.

The challenge of efficient design recommendation is further complicated by the rapid pace of market evolution. During the extended periods required for thorough research and data synthesis, competitors may introduce new concepts or products, potentially diminishing the relevance or market impact of the original design. This creates a technical challenge of balancing thorough analysis with rapid development cycles.

Current market solutions attempt to address these challenges through specialized artificial intelligence tools. While individual tools leverage generative AI to assist in specific phases of the design cycle-research, synthesis, ideation, design, testing, and marketing—no comprehensive technical solution exists for seamless integration across all phases. The technical challenge of coordinating multiple AI models across different design phases, while maintaining data consistency and context, remains unaddressed in existing solutions.

The fragmented nature of current AI-driven design tools creates significant technical inefficiencies. The absence of standardized data transformation protocols between different phases necessitates manual intervention for data transfer and context preservation. This lack of technical integration between AI models not only introduces potential errors and inconsistencies but also undermines the coherence of the overall design process. The challenge extends beyond mere workflow efficiency to the fundamental problem of maintaining data integrity and contextual relevance across different AI-powered design operations. Standalone AI tools are often specialized for individual tasks like research (e.g., gathering user data), synthesis (e.g., creating personas), or ideation (e.g., generating concepts). While these tools are effective in isolation, they may not easily communicate or share insights with other tools in the workflow.

The time-intensive nature of design processes, coupled with rapidly evolving market conditions and the limitations of disconnected tools, continues to impede efficient design development and implementation. These constraints particularly impact organizations striving to maintain competitive advantage through rapid, yet thorough design iterations.

### SUMMARY

Disclosed embodiments relate to a method and system for automated design recommendation. A unified design framework of the system includes a graphical user interface (GUI) that receives a user input and presents an output. An integration controller of the unified design framework coordinates data transfers between a plurality of design modules and enables automated data flow between consecutive modules to maintain design context across module transitions. The plurality of design modules such as, a research and strategy module utilizes a first LLM to evaluate product feasibility and strategy, a synthesis module utilizes a second LLM to generate synthetic user data based on the user input, an ideation module utilizes a third LLM to transform the synthetic user data into design requirements, a design module utilizes a fourth LLM to create design concepts based on the design requirements, and a go-to-market module utilizes a fifth LLM to generate market strategies based on the design concepts.

These and other features and advantages of the present disclosure may be appreciated from a review of the following detailed description of the present disclosure, along with the accompanying figures in which like reference numerals refer to like parts throughout.

### BRIEF DESCRIPTION OF THE FIGURES

FIG. 1 is a diagram that illustrates an exemplary environment 100 within which various embodiments of the present disclosure may function.

FIG. 2 is a diagram that illustrates the system 102 for automated design recommendation using a unified design framework, in accordance with an embodiment of the disclosure.

FIG. 3 is an exemplary diagram 300 that illustrates automated design recommendation for a given input by a user, in accordance with an embodiment of the disclosure.

FIG. 4 is a diagram that illustrates a flow chart 400 for a method for automated design recommendation using a unified design framework, in accordance with an embodiment of the disclosure.

### DESCRIPTION

Pursuant to various embodiments of the present disclosure, method and system provides automated design recommendation. A unified design framework of the system includes a graphical user interface (GUI) that receives a user input and presents an output. An integration controller of the unified design framework coordinates data transfers between a plurality of design modules and enables automated data flow between consecutive modules to maintain design context across module transitions. The plurality of design modules such as, a research and strategy module utilizes a first LLM to evaluate product feasibility and strategy, a synthesis module utilizes a second LLM to generate synthetic user data based on the user input, an ideation module utilizes a third LLM to transform the synthetic user data into design requirements, a design module utilizes a fourth LLM to create design concepts based on the design requirements, and a go-to-market module utilizes a fifth LLM to generate market strategies based on the design concepts.

In one or more embodiments, the unified design framework integrates the requirements of each phase in the design cycle into a single, cohesive tool that is powered with by generative AI and a robust practical knowledge base. The combination enhances the unified design framework's capability to guide users seamlessly through the design process, ensuring that every phase builds on the insights of the previous one.

In one or more embodiments, the unified design framework is configured to demand only a few significant inputs from the user that alone can fuel the framework's operation, guiding the user all the way from obtaining synthesized research data, through ideation and wireframing, to finally testing designs. Alternatively, depending on the phase of the design cycle the user is currently in, the unified design framework requires data relevant only to that specific phase, providing tailored, relevant, and reliable results.

In one or more embodiments, the LLMs are trained with a tailored set of questions, instructions, and principles grounded in practical experience, which equips the LLMs with the ability to analyze user inputs with the expertise and precision of a professional designer, ensuring that the system processes each piece of information in alignment with design best practices.

In one or more embodiments, the unified design framework also leverages the Natural Language Processing (NLP) capabilities of generative AI to provide real-time clarifications on queries related to the information provided. By utilizing NLP, the system can interpret and respond to user inquiries in natural language, enabling a more interactive and dynamic user experience.

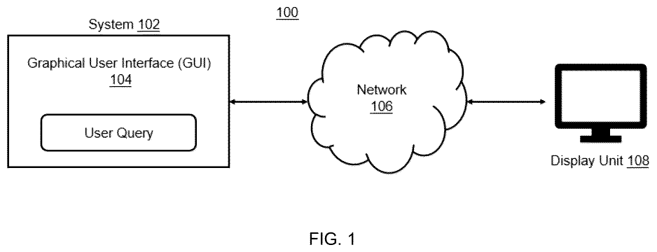

FIG. 1 is a diagram that illustrates an exemplary environment 100 within which various embodiments of the present disclosure may function. Referring to FIG. 1, the environment 100 comprises a system 102, a GUI 104, a network 106, and a display unit 108.

The system 102 enables the unified design framework to integrate the requirements of each phase in the design cycle into a single, cohesive tool that is powered by Gen-AI and a robust practical knowledge base. The combination enhances the unified design framework's capability to guide a user seamlessly through the design process, ensuring that every phase builds on the insights of the previous one.

The GUI 104 of the system 102 refers to an interactive platform where the user can enter an input. The GUI 104 is also designed to receive inputs of various types, allowing for flexible and adaptable user interactions.

In one or more embodiments, the GUI 104 is configured to enable independent access to each module of the plurality of design modules. The configuration allows users to interact with and operate each module individually, giving them the flexibility to start at any phase of the design cycle or focus on specific stages without requiring progression through the entire process.

In one or more embodiments, the GUI 104 is also configured to display module-specific input interfaces. The input interfaces are tailored to the unique requirements of each design module, providing the user with the appropriate tools, fields, and options relevant to the phase they are working in. By presenting the input interfaces, the GUI 104 allows the user to interact seamlessly with the specific module at hand, facilitating the efficient input of data and enabling the system 102 to generate outputs aligned with the user's current design objectives.

In one or more embodiments, the GUI 104 is configured to present real-time updates of operations from each accessed module. The feature allows the user to track the progress of tasks and view live feedback as each module performs its respective function. Whether the user is working on research and strategy, ideation, design, or testing, the GUI 104 ensures that all actions and results are dynamically reflected, providing up-to-date information without requiring manual refreshes or transitions between phases.

In some non-limiting embodiments, the GUI 104 is designed to receive a diverse range of input types and forms, accommodating various user preferences and operational needs such as keyboard and mouse interactions, as well as modalities like touch, voice recognition, and natural language processing.

The network 106 includes communication networks operable to facilitate communication, either wirelessly or wired. The network 106 connects a plurality of computer systems. The network 106 may comprise, for example, an intranet, local area network, wide area network, the internet, or other wireless network.

In one or more embodiments, the network 106 facilitates connection between the system 102 and the display unit 108 via one or more communication channels.

In one or more embodiments, the display unit 108 is configured to present the design outputs to the user in an interactive manner. The display unit 108 can include, but is not limited to, devices such as, interactive dashboards, touchscreen displays, projection systems, and wearable displays.

In some non-limiting embodiments, the display unit 108 can be located within an enterprise environment or at any other remote location, providing flexibility in accessing and presenting insights to users. For instance, in an enterprise setting, the display unit 108 could be integrated into centralized workstations or conference room systems, facilitating collaborative decision-making among teams. Conversely, in remote locations, the display unit 108 could be accessed via portable devices such as laptops, tablets, or smartphones, ensuring seamless connectivity and uninterrupted workflow regardless of the user's physical location.

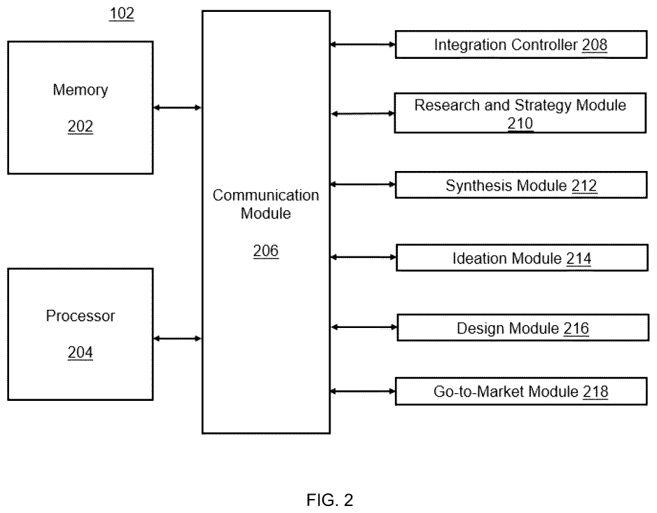

FIG. 2 is a diagram that illustrates the system 102 for automated design recommendation using the unified design framework, in accordance with an embodiment of the disclosure. Referring to FIG. 2, the system 102 includes a memory 202, a processor 204, a communication module 206, an integration controller 208, a research and strategy module 210, a synthesis module 212, an ideation module 214, a design module 216, and a go-to-market module 218.

The memory 202 may comprise suitable logic, and/or interfaces, that may be configured to store instructions (for example, computer-readable program code) that can implement various aspects of the present disclosure.

The processor 204 may comprise suitable logic, interfaces, and/or code that may be configured to execute the instructions stored in the memory 202 to implement various functionalities of the system 102 in accordance with various aspects of the present disclosure. The processor 204 may be further configured to communicate with various modules of the system 102 via the communication module 206.

The integration controller 208 may comprise suitable logic, code, and/or interface that may be configured to coordinate data transfers between the plurality of design modules. The integration controller 208 may be configured to ensure that data generated or modified in one module is effectively communicated to the next module in the process, maintaining consistency and logical connections throughout the workflow. This seamless data coordination is essential for creating a unified design experience, as it enables the system 102 to progress naturally from research and strategy to ideation, design, and ultimately, go-to-market strategy development, without the need for manual data handling between steps.

The integration controller 208 may be configured to manage both the timing and integrity of data as it moves between modules. It tracks dependencies and ensures that the necessary data outputs from earlier stages are available and correctly formatted for later stages. For example, once the ideation module 214 generates design requirements, the integration controller 208 ensures that these concepts are properly delivered to the design module 216 for generating design concepts.

In one or more embodiments, the transfer is not just about moving data, it also involves ensuring that the data is in the appropriate format and context, so that each subsequent module can effectively process and use it. By coordinating these data flows, the integration controller 208 may be configured to help create a streamlined and efficient workflow that maximizes the utility of each module while minimizing the chances of errors or data misalignment across the entire design cycle.

In one or more embodiments, the integration controller 208 may be further configured to maintain design context across module transitions ensuring that each module in the design cycle operates with a coherent understanding of the project as it evolves. This means that, as data is passed from one module to the next, the integration controller 208 may be configured to not only transfer the raw information but also preserve the underlying context, including design intentions, user preferences, and project goals.

For instance, when the design concepts created in the design module 216 are passed to the go-to-market 218 to generate market strategies, the integration controller 208 may be configured to ensure that the context of user needs, design objectives, and project constraints remain intact. The holistic approach prevents situations where design decisions are made in isolation, facilitating a more cohesive and integrated design process that reflects the evolving nature of the project and maintains alignment with the overarching goals.

In one or more embodiments, the integration controller 208 may be further configured to track data dependencies between modules. By keeping track of which data is required by each module and how it relates to the outputs of other modules, the integration controller 208 may be configured to help ensure that each phase has access to the most relevant and up-to-date information. This tracking of data dependencies also helps to avoid redundant data transfers and ensures that the necessary data is available when needed, reducing delays and optimizing the flow of the design process.

The integration controller 208 may be configured to enable automated data flow between consecutive modules. The automation enhances the efficiency and speed of the design cycle by reducing the time spent on data preparation and transfer between modules. Each module within the system 102 generates outputs that serve as inputs for the next, and the integration controller 208 orchestrates this handoff seamlessly, eliminating potential bottlenecks and minimizing errors that could arise from manual data entry.

The research and strategy module 210 may comprise suitable logic, code, and/or interfaces that may be configured to evaluate product feasibility and strategy based on the user input. For instance, the user input may be feasibility pitch for the product. Further, the user input may comprise target group parameters comprising demographic characteristics, behavioral patterns, and user preferences. Furthermore, the user input may comprise product details comprising product name, product objectives, market positioning, and functional requirements.

In one or more embodiments, the research and strategy module 210 is configured to evaluate the feasibility and strategy of a proposed product or service based on the user input. The research and strategy module 210 may employ various analytical techniques and scoring mechanisms to provide insights into the feasibility and strategic direction of the product.

In one or more embodiments, the research and strategy module 210 utilizes a first LLM to analyze the user input and evaluate the feasibility and strategy of the proposed product. The first LLM is configured with parameters to evaluate product feasibility and strategy based on the user input. The first LLM is pre-trained on a corpus of domain-specific and general knowledge, enabling it to perform context-aware evaluations of user inputs. The evaluation involves assessing the alignment of the proposed product or service with market trends, user needs, and strategic objectives. By employing advanced natural language understanding and reasoning capabilities, the first LLM may also examine factors such as potential demand, competitive landscape, and resource availability.

In some non-limiting embodiments, the research and strategy module 210 identifies possible constraints or risks, ensuring that the product or service aligns with the user's intended objectives. Configured with customizable parameters, the first LLM tailors its analysis to the specific requirements of the domain, thereby offering precise and actionable insights for validating product feasibility and developing robust strategies.

In one or more embodiments, the research and strategy module 210, by utilizing the first LLM, is configured to execute specific operational functions.

The research and strategy module 210 conducts a comprehensive feasibility analysis by evaluating the user-provided feasibility pitch for the product or service and generates detailed scores that summarize its feasibility and implementation potential. These scores encompass a Feasibility Verdict that indicates the viability of the product pitch, wherein the research and strategy module 210 may determine the pitch to be feasible while identifying necessary adjustments. The analysis also includes a Predicted Demand Percentage that estimates the potential market demand for the product, typically expressed as a range such as 70-80%. Additionally, the research and strategy module 210 generates a Uniqueness Score that quantifies the novelty of the product concept on a defined scale, such as 6.5 out of 10, which serves to guide differentiation strategies.

The research and strategy module 210 further provides strategic frameworks and templates to aid users in understanding research outcomes and target formulation. Within these frameworks, the module defines key Business KPIs, wherein the research and strategy module 210 may suggest specific targets, such as achieving a global digital platform reach of 10-15 million global users within a two-year timeframe during the discovery phase.

The synthesis module 212 may comprise suitable logic, code, and/or interfaces that may be configured to create synthetic user data from the user input. The synthesis module 212 interprets the user's input to create the synthetic user data that reflects the intended user demographics or market segment, forming a robust foundation for subsequent design phases. The synthetic user data generated by the synthesis module 212 may include a wide range of user-centric insights designed to inform and guide the subsequent stages of the design cycle. The synthetic user data may include, but not limited to, simulated demographic profiles, user preferences, behavior patterns, and usage scenarios that align with the target audience specified by the user. For instance, the synthetic user data may include predictive insights, such as anticipated trends or emerging behaviors within the specified demographic.

In one or more embodiments, the synthesis module 212 may be configured to utilize a second LLM to generate synthetic user data based on the user input. The second LLM is configured with parameters for synthetic user data generation, and user behavior simulation, allowing it to create realistic, contextually relevant data that reflects the characteristics and preferences of the intended user demographic. By incorporating a range of inputs such as demographic details, behavioral patterns, and user preferences, the second LLM can simulate a diverse set of user profiles and behaviors.

In one or more embodiments, the synthesis module 212 may be further configured to simulate user interviews, analyze user behavior patterns, and produce market insights based on the simulated data. By leveraging the second LLM and advanced data generation techniques, the synthesis module 212 may be configured to create realistic interview scenarios that reflect diverse user perspectives, preferences, and needs.

The ideation module 214 may comprise suitable logic, code, and/or interfaces that may be configured to transform the synthetic data into design requirements. The ideation module 214 may be configured to covert the synthetic data into design requirements that can be used in subsequent phases of the design cycle. For instance, the requirements may include, but are not limited to, functional specifications, user interface guidelines, and other design parameters that directly inform the creation of design concepts and prototypes.

In one or more embodiments, the ideation module 214, by utilizing the third LLM, transforms the synthetic data into the design requirements. The third LLM is configured with parameters for transforming the synthetic data into design requirements, enabling it to analyze the synthetic data generated by the synthesis module 212 and identify key trends, user needs, and design opportunities. Through advanced machine learning algorithms, the third LLM may detect patterns within the data, such as recurring user preferences or common behavior traits, and extract relevant design requirements from these patterns.

In one or more embodiments, the ideation module 214 may also be configured to analyze unstructured data from the synthetic user data. The unstructured data may include, but not limited to, free-text responses, user comments, feedback, or other narrative forms of information that are not organized in predefined formats. By utilizing NLP and advanced machine learning techniques, the ideation module 214 may be configured to extract meaningful insights and patterns from this unstructured data. The analysis may involve, but may not be limited to identifying key themes, sentiments, or user concerns that are relevant to the design requirements, which might not be immediately apparent in structured datasets. By incorporating both structured and unstructured data, the ideation module 214 may be configured to ensure a comprehensive understanding of user needs, leading to more nuanced and informed design requirements that reflect the complexities of real-world user behavior and preferences.

In one or more embodiments, the ideation module 214 may also be configured to identify design patterns and user needs. By analyzing both structured and unstructured data from the synthetic user data, the ideation module 214 may be configured to detect recurring themes, preferences, and behaviors that inform the design process, which may include recognizing common design patterns, such as user interface preferences, interaction flows, or functionality requirements, as well as identifying specific user needs that must be addressed in the design.

In one or more embodiments, the ideation module 214 is also configured to generate structured design requirements. After analyzing the synthetic user data and identifying relevant patterns, user needs, and design opportunities, the ideation module 214 may be configured to organize these insights into a clear, structured format that can be directly applied to subsequent design phases. The structured format may include categories such as, but not limited to, functional specifications, usability criteria, interaction design principles, and performance requirements, ensuring that all design considerations are well-defined and easy to interpret.

In one or more embodiments, the ideation module 214 may be further configured to present multiple ideation methodologies for user selection, which allows the user to choose from a range of structured approaches to idea generation, such as brainstorming, mind mapping, design thinking, or other creative frameworks, depending on the user's preferences and the specific needs of the project. By offering flexibility in methodology, the ideation module 214 may be configured to accommodate diverse workflows and encourages a more tailored approach to the design process.

In one or more embodiments, the ideation module 214 may further be configured to receive user selection of an ideation method, which allows the user to choose a specific approach to generating design concepts, such as brainstorming, user-centered design, design thinking, or other ideation techniques. Once the user selects a method, the ideation module 214 may be configured to tailor the concept generation process to align with the chosen methodology.

In one or more embodiments, the ideation module 214 is further configured to adapt the ideation process based on the selected method. Upon receiving the user's choice of an ideation methodology, the design ideation 214 may be configured to adjust its logic, parameters, and operations to align with the specific characteristics and goals of the chosen approach. For example, if the user selects a design thinking method, the ideation module 214 may be configured to prioritize user empathy and problem-solving, while in a brainstorming method, it may focus on idea generation and creativity.

The design module 216 may comprise suitable logic, code, and/or interfaces that may be configured to recommend design concepts based on the design requirements received from the ideation module 214. Once the ideation module 214 has transformed the synthetic user data into structured design requirements, the design module 216 may be configured to take these inputs to create innovative and practical design concepts. The process may involve exploring a range of potential solutions, brainstorming ideas, and leveraging creative algorithms to generate a variety of design alternatives that align with the identified user needs and design goals.

In one or more embodiments, the design module 216 may be configured to utilize the fourth LLM to generate design concepts based on the design requirements. The fourth LLM is specifically configured with parameters for concept generation and feasibility analysis, enabling it to produce innovative design ideas that not only align with the user's specified requirements but also consider the practicality and viability of each concept.

In some non-limiting embodiments, through its advanced algorithms, the fourth LLM explores a wide range of creative possibilities, ensuring that the generated concepts are both novel and realistic, taking into account constraints such as functionality, user experience, and technical feasibility. By leveraging the fourth LLM, the design module 216 may be configured to help streamline the creative process, providing the user with a selection of well-structured, feasible design concepts that can be further refined and developed in subsequent stages of the design cycle.

In one or more embodiments, the design module 216 may be further configured to generate multiple design alternatives based on the design requirements. By utilizing the structured design requirements from the ideation module 214, the design module 216 may be configured to explore a range of possible design solutions, producing several distinct alternatives that address the identified user needs, functional specifications, and aesthetic preferences. The alternatives may vary in terms of layout, interaction flow, feature prioritization, and visual style, allowing the user to evaluate a spectrum of approaches to the design challenge.

In one or more embodiments, the design module 216 may be further configured to evaluate feasibility of each alternative. Once multiple design alternatives have been generated, the design module 216 may be configured to assess each concept's practicality by considering factors such as, but not limited to, technical constraints, resource availability, user experience, and alignment with the project's functional requirements. The evaluation process may involve running simulations, comparing against predefined feasibility criteria, or leveraging machine learning models to predict the likelihood of successful implementation.

In one or more embodiments, the design module 216 may further be configured to rank design concepts based on predefined criteria. After generating multiple design alternatives and evaluating their feasibility, the design module 216 may be configured to apply a set of predefined criteria to rank each concept according to factors such as, but not limited to, user needs alignment, technical feasibility, innovation, cost-effectiveness, and overall impact. The criteria may be customized based on the specific goals of the design project, allowing the user to prioritize aspects like usability, performance, aesthetics, or sustainability.

In one or more embodiments, the design module 216 includes a design knowledge base storing extracted design principles from prior implementations. The knowledge base serves as a repository of best practices, design patterns, and insights gleaned from previous projects, allowing the design module 216 to leverage this accumulated knowledge to guide generation of new prototypes.

In some non-limiting embodiments, the design knowledge base is configured to store and categorize design patterns based on implementation context, which allows the design module 216 to select and apply the most relevant design patterns depending on the specific requirements and constraints of the project, such as, but not limited to, the target user group, industry standards, or platform specifications. By organizing design patterns in this manner, the knowledge base enables more efficient decision-making and ensures that the design process leverages the most appropriate solutions for each unique context. For example, patterns for mobile app interfaces may be categorized separately from those for web applications or enterprise software, allowing the design module 216 to quickly access the right resources based on the project's needs, resulting in more relevant and effective prototypes.

In some non-limiting embodiments, the design knowledge base is configured to maintain quality standards across design iterations. This functionality ensures that, as the design evolves through multiple iterations, it consistently adheres to predefined quality benchmarks such as usability, accessibility, responsiveness, and visual consistency. By tracking and referencing these standards, the knowledge base acts as a safeguard, helping to preserve the integrity of the design throughout the development process. As design concepts are refined or modified, the knowledge base provides a reference for maintaining high-quality user experiences, preventing deviations from established best practices, and ensuring that the final prototype meets both functional and aesthetic criteria.

In some non-limiting embodiments, the design knowledge base is configured to update automatically based on validated design outcomes. As design iterations progress and real-world testing or user feedback is collected, the knowledge base is dynamically updated with new insights, patterns, and design solutions that have proven successful. This ensures that the knowledge base remains current and reflective of the latest design trends, user preferences, and industry standards. By incorporating validated outcomes, the design knowledge base continually evolves, offering more accurate and reliable references for future design projects.

In one or more embodiments, the design module 216 includes a component repository containing white-labeled design elements and reusable templates. The repository serves as a collection of pre-designed components, such as buttons, navigation bars, forms, icons, and other UI elements, which can be easily integrated into the prototype. The components are white labeled, meaning they are customizable and can be tailored to match the specific branding and visual identity of the project. Additionally, the repository includes reusable templates that provide structured layouts for common design patterns, helping to streamline the design process and maintain consistency across the prototype.

In one or more embodiments, the design module 216 may be configured to enable automated extraction and white labeling of design components. This capability allows the design module 216 to identify reusable design elements from existing prototypes, templates, or design patterns, and adapt them for new projects by removing brand-specific attributes. The extracted components, such as buttons, forms, icons, or navigation menus, are then customized to align with the visual identity and functional requirements of the current project.

In one or more embodiments, the design module 216 may be configured to enable automated application of design principles from the knowledge base. By leveraging stored principles such as usability guidelines, aesthetic standards, accessibility requirements, and industry best practices, the design module 216 may be configured to ensure that these principles are seamlessly integrated into the design process. This automation allows the design module 216 to evaluate design components and layouts in real time, applying appropriate adjustments to align with the established principles. For instance, the design module 216 may be configured to automatically optimize color contrast for accessibility, adjust spacing for visual balance, or enhance navigation flows for improved usability.

In one or more embodiments, the design module 216 may be configured to enable automated prototype refinement based on LLM recommendations. By analyzing the prototype against design requirements, user feedback, and stored design principles, the LLM generates targeted suggestions for enhancing various aspects of the prototype, such as layout, functionality, and user interaction. The design module 216 may be configured to incorporate these recommendations into the prototype, making iterative adjustments automatically to improve alignment with user needs and project goals.

The go-to-market module 218 may comprise suitable logic, code, and/or interfaces that may be configured to generate market strategies based on design concepts. The go-to-market module 218 may be configured to analyze the design concepts in the context of target demographics, industry trends, and competitive landscapes to develop comprehensive strategies for successful market entry. The go-to-market module 218 may be configured to consider factors such as positioning, pricing, promotional tactics, and distribution channels to create actionable plans tailored to the product's unique attributes.

In one or more embodiments, the go-to-market module 218 may be configured to utilize a fifth LLM to generate the market strategies. The fifth LLM is configured with parameters for marketing content generation and campaign strategy development, enabling it to craft detailed and targeted approaches for product promotion and distribution. By analyzing data from validated prototypes, user demographics, market trends, and competitor benchmarks, the fifth LLM generates tailored strategies, including messaging frameworks, branding guidelines, and promotional tactics.

In one or more embodiments, the go-to-market module 218 may be configured to receive brand specifications, target audience parameters, and market requirements. In one or more embodiments, the go-to-market module 218 may be configured to receive brand specifications, target audience parameters, and market requirements. The inputs allow the go-to-market module 218 to tailor the market strategy to align with the product's branding and the specific needs of the target audience. Brand specifications may include elements such as, but not limited to, brand identity, values, and messaging tone, while target audience parameters encompass demographic data, user preferences, and behavioral insights. Market requirements may involve factors such as, but not limited to, competitive positioning, pricing strategies, and industry trends.

In one or more embodiments, the go-to-market module 218 may be configured to analyze market positioning opportunities. In one or more embodiments, the go-to-market module 218 may be configured to analyze market positioning opportunities. This functionality allows the go-to-market module 218 to assess the product's potential within various market segments, identifying areas where it can differentiate itself from competitors and capture value.

In one or more embodiments, the go-to-market module 218 is configured to generate user acquisition strategies. The feature allows the go-to-market module 218 to develop targeted plans for attracting and converting potential customers based on insights from the validated prototypes, market analysis, and audience parameters. By leveraging data on user demographics, preferences, and behaviors, the go-to-market module 218 may be configured to formulate strategies that include optimized digital marketing campaigns, influencer partnerships, referral programs, and content marketing tactics. The strategies are designed to engage the right users at the right time, driving user adoption and building brand loyalty from the outset.

In one or more embodiments, the go-to-market module 218 may be further configured to analyze market trends using the synthetic user data. By leveraging the insights derived from the synthetic data generated during the research phase, the go-to-market module 218 may be configured to identify emerging trends, shifts in consumer behavior, and evolving market demands. The analysis enables the go-to-market module 218 to refine the product's positioning, adjust its marketing strategies, and anticipate potential opportunities or threats in the market.

In one or more embodiments, the go-to-market module 218 may be further configured to recommend channel-specific marketing strategies. The functionality enables the go-to-market module 218 to tailor marketing tactics to different platforms and distribution channels, ensuring that each channel is leveraged effectively to reach the target audience. By analyzing user behavior, market trends, and platform-specific dynamics, the go-to-market module 218 may be configured to suggest optimal strategies for various channels such as social media, email marketing, search engine advertising, content marketing, and influencer partnerships.

In one or more embodiments, the go-to-market module 218 may be further configured to generate performance metrics for proposed strategies. The feature allows the go-to-market module 218 to evaluate and quantify the potential effectiveness of the suggested marketing strategies before they are implemented. By using historical data, synthetic user data, and predictive models, the go-to-market module 218 may be configured to generate key performance indicators (KPIs) such as customer acquisition cost, conversion rates, user engagement levels, and return on investment (ROI) for each proposed strategy. The metrics enable stakeholders to assess the viability of different strategies, make data-driven decisions, and optimize marketing efforts for maximum impact.

In one or more embodiments, each module of the plurality of design modules is configured to present intermediate outputs for user review. As the user progresses through the design cycle, each module provides interim results or deliverables that offer insight into the work being completed. This enables the user to track the design process at various stages, ensuring that each phase aligns with the overall project objectives. The intermediate outputs may include, but are not limited to, visual mockups, data analysis summaries, design concept sketches, or progress reports, depending on the nature of the module in use. Presenting these outputs at each stage allows for ongoing feedback, ensuring that the design process remains iterative and responsive to user inputs.

In one or more embodiments, the presentation of intermediate outputs facilitates a collaborative workflow, allowing the user to make adjustments and refinements as necessary before moving on to the next phase. Whether the user is reviewing a synthesized data set, evaluating a set of design concepts, or assessing a prototype's functionality, these outputs serve as touchpoints for evaluation and decision-making. In some embodiments, the user may be able to interact directly with the intermediate outputs, offering the ability to make real-time adjustments or provide additional input to the system 102.

In one or more embodiments, each module of the plurality of design modules is configured to receive user feedback through the GUI 104. The feedback mechanism allows the user to actively participate in shaping the direction of the design process. As the user interacts with the intermediate outputs or ongoing results presented by the various design modules, they can provide input, suggestions, or critiques that inform the system's 102 subsequent actions. This feedback can take various forms, including textual comments, numeric ratings, selections from predefined options, or even direct modifications to elements within the interface.

The integration of user feedback into the GUI 104 enables a dynamic and iterative design cycle, where user input is continuously incorporated into the workflow. For instance, after reviewing a set of design concepts or prototypes, the user may suggest refinements, adjustments to design elements, or provide clarifications regarding their preferences. The feedback is then processed by the relevant design module, which can modify its approach, update its output, or refine the results based on the user's input.

In one or more embodiments, each module of the plurality of design modules is configured to refine the outputs using the respective LLM based on the user feedback. When the user provides feedback on the intermediate outputs generated by a module, the LLM within that module processes the feedback and makes the necessary adjustments to improve or modify the design output. For instance, if the user expresses a preference for a specific design element or requests a change in functionality, the LLM utilizes the feedback to adjust its models and algorithms to refine the output in line with the user's input.

The LLM's role in refining outputs based on feedback is a critical aspect of the system's 102 ability to adapt to the evolving design requirements throughout the various phases of the design cycle.

In one or more embodiments, each module of the plurality of design modules is configured to proceed to subsequent operations upon user confirmation. The mechanism allows the system 102 to operate in a controlled, user-guided manner, where each step in the design process is subject to the user's approval before moving forward. For example, after a user reviews the output of a particular module, such as the research and strategy, synthesis, or ideation modules, they can confirm whether the current results meet their expectations and align with the project goals.

This user-driven progression provides a seamless workflow where the user has the final say on the validity and quality of the work produced at each phase. By incorporating user confirmation before advancing, the system 102 minimizes the risk of skipping critical steps or moving forward with incomplete or unsatisfactory results. It also fosters a collaborative approach to design, where the user's input plays an integral role in shaping the outcome of the project. The ability to confirm outputs before proceeding ensures that each phase is finalized with a sense of confidence, allowing for more accurate and refined outcomes in subsequent operations.

In some non-limiting embodiments, each LLM is configured through training with design-specific data comprising a well-documented design processes, strategy templates such as, but not limited to, Business Model Canvas, Full-funnel KPIs, SWOT analysis and more, user research outcomes like Personas and User Journeys, Design principles by Industry and Use Case, validated UX design templates and components, integration with domain-specific instructions, and implementation of design-focused response parameters. The training enables the LLMs to understand and analyze user inputs in a way that reflects professional design practices, ensuring that the outputs generated align with established standards and methodologies in the design field.

The inclusion of documented design processes and user research outcomes in the training data allows the LLMs to incorporate industry best practices, user preferences, and behavioral insights into the design workflow. Additionally, the integration of design patterns and validated design solutions ensures that the system 102 can recommend or generate outputs that are proven effective in real-world applications. Domain-specific instructions and response parameters further refine the LLMs'understanding of particular design challenges, enabling them to generate solutions that adhere to the nuances of specific industries or design contexts.

The system 102 is further configured to create interactive prototypes based on the design concepts generated by the design module 216. Specifically, the system 102 leverages the capabilities of LLM to transform the design concepts into detailed prototype representations. The interactive prototypes incorporate dynamic elements such as user interface behaviors, animations, and functional workflows, enabling users to experience and evaluate the proposed designs in a simulated environment. The system 102 ensures that these prototypes closely align with the design requirements established in earlier stages, facilitating iterative refinement based on user feedback or additional inputs. By offering interactive prototypes, the system 102 bridges the gap between abstract design concepts and tangible implementations, supporting comprehensive validation of usability, functionality, and overall user experience before proceeding to production stages.

In some non-limiting embodiments, the system 102 may comprise a testing module that is also configured to validate the interactive prototypes. The testing module may comprise suitable logic, code, and/or interfaces that may be configured to evaluate the prototypes against predefined usability criteria, functional requirements, and design principles to ensure their effectiveness and reliability. By leveraging advanced algorithms and integrated tools, the testing module may be configured to simulate real-world scenarios, conduct performance assessments, and identify potential usability issues.

In some non-limiting embodiments, the testing module may be configured to utilize a sixth LLM to validate the interactive prototypes and designs. The sixth LLM is configured with parameters for validation and optimization assessment, enabling it to analyze the prototypes for compliance with usability standards, functionality, and performance metrics. By evaluating aspects such as user interaction flows, accessibility, responsiveness, and visual coherence, the sixth LLM identifies areas of improvement and potential issues. Additionally, the sixth LLM provides optimization recommendations to enhance prototype quality, ensuring that the designs align with both user expectations and project objectives.

The testing module may be further configured to simulate user testing scenarios. By leveraging advanced algorithms and contextual data, the testing module may be configured to recreate real-world interactions that mimic how end-users would engage with the prototypes. The simulations may include tasks such as, but not limited to, navigating the interface, completing specific workflows, or interacting with dynamic elements. The testing module may be configured to analyze user behavior patterns during these simulations to identify usability challenges, bottlenecks, and points of friction.

The testing module may be further configured to analyze interaction patterns. By capturing and evaluating how users engage with the interactive prototypes during simulated or actual testing, the testing module may be configured to identify trends and anomalies in user behavior. The analysis includes tracking navigation flows, click-through rates, dwell times, and task completion rates to assess usability and efficiency. The testing module may be configured to leverage this data to pinpoint design elements that may cause confusion or delay and suggests improvements to enhance user engagement.

The testing module may be further configured to generate optimization recommendations. By leveraging insights derived from analyzing user interaction patterns, usability metrics, and performance benchmarks, the testing module may be configured to identify specific areas within the prototype that require enhancement. The recommendations may include adjustments to layout, navigation flows, responsiveness, or accessibility features to improve the overall user experience. The testing module may be configured to ensure that these suggestions are aligned with established design principles and project objectives, providing actionable guidance for refining the prototype.

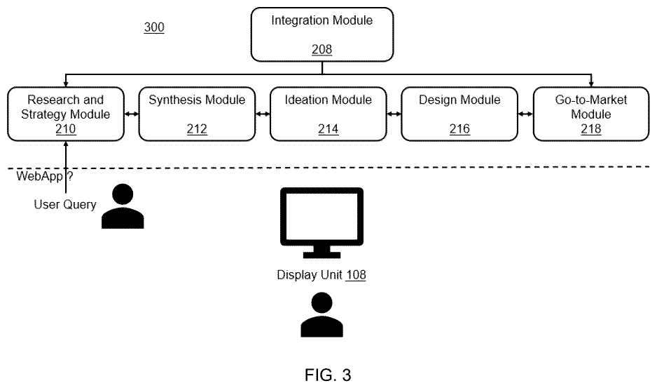

FIG. 3 is an exemplary diagram 300 illustrating automated design recommendation for a given input by a user, in accordance with an embodiment of the disclosure.

As shown in FIG. 3, the user begins the design process by interacting with the GUI 104. The user provides a set of input parameters to initiate the design cycle. For instance, the user may be a product manager at a tech company looking to design a new holistic health webapp. The input provided could include:
Brand Specifications: The user inputs basic details about the brand such as name, industry, key services and offerings, as well as information on the brand's values, such as “Emphasizing the importance of a balanced approach to wellness”, “Fostering a supportive and inclusive environment”, and “Providing trustworthy and evidence-based health information.” The user also specifies the brand's geographical reach as “Strong presence in North America, Europe, and Australia” and quantify their current user base.
Product Details: The product is a webapp with wearable integration with features such as personalized wellness plans, guided meditations, nutritional guidance etc., with a goal to provide seamless integration with smartphones and desktop. The user specifies the competitive edge that the product has over other similar products in the market, such as “Integrated Approach: Combining physical, mental, and nutritional health in one platform”, “AI-Powered Personalization: Leveraging AI to create highly tailored wellness plans”, etc.
Target Audience Parameters: The user specifies that the target market consists of fully-or partly employed young professionals aged 25-50, living in urban and suburban areas with high internet penetration.

The system 102 processes these inputs through its interconnected modules, each utilizing specialized LLMs to transform the initial requirements into subsequent design artifacts. The following sections detail the data transformations and outputs at each stage:

In accordance with the exemplary embodiment, the research and strategy module 210 processes the user input to evaluate and produce feasibility and strategy insights for the proposed product or service. The insights include a comprehensive evaluation of the product-to-be's feasibility and implementation prospects, as well as structured frameworks to guide the design process.

The research and strategy module 210 generates quantitative scores to summarize the feasibility and strategy:
A feasibility verdict indicating the pitch is feasible with minor adjustments.
A predicted demand percentage, estimated at 70-80%, reflecting potential user interest and market readiness.
A uniqueness score, rated at 6.5 out of 10, assessing the distinctiveness of the proposed product relative to competitors.

The research and strategy module 210 outputs structured frameworks and templates to provide users with a clear understanding of key research findings and targets. For example:
Key Business KPIs, such as a target of achieving 10-15 million users globally within two years, aligned with the global digital platform reach expected in the Discovery phase.
A Business Model Canvas, identifying mobile web as the primary platform for delivering personalized wellness plans, tracking, and content, while desktop serves as an additional platform for users preferring larger screens.
A SWOT analysis, highlighting opportunities such as the increasing global focus on holistic wellness and mental health awareness, as well as the rising adoption of wearables and AI for personal health management.

The research and strategy module 210 also identifies detailed research areas, providing a granular breakdown of factors contributing to the generated scores and frameworks. These areas may include:
Demographics and psychographics, outlining user characteristics and preferences.
Monetization strategies, suggesting approaches for revenue generation.
Legal barriers, identifying regulatory considerations for product deployment.
Market research, highlighting trends, competition, and growth opportunities.

In accordance with the exemplary embodiment, the synthesis module 212 processes user input and insights derived from the research and strategy module 210 to generate synthetic user data. This data serves as the foundation for creating structured design requirements that align with the target audience's needs and preferences.

In one or more embodiments, the synthesis module 212 produces detailed user personas that represent comprehensive profiles of the target user groups. These personas include:
Demographics and psychographics, such as age, occupation, lifestyle preferences, and digital experience levels.
Insights into goals, needs, and pain points, providing actionable understanding of what users seek in the product and their challenges.
How-Might-We statements, framing potential solutions to challenges faced by the user group in a design-thinking context.

In one or more embodiments, the synthesis module 212 performs persona validation, offering a detailed breakdown of how data from user inputs and the research and strategy module 210 contributed to the creation of the personas.

In one or more embodiments, the synthesis module 212 outputs qualitative and quantitative insights derived from the personas. These insights include:
Statistical observations, such as behavioral trends relevant to the digital product idea, enabling data-driven design decisions.
Derived insights, such as preferences and habits extrapolated from the statistical data, providing further context for design requirements.

In one or more embodiments, the synthesis module 212 generates simulated user interviews using NLP techniques to offer deeper insights into user expectations. These simulated interviews include:
Sentiment-analyzed feedback, providing a detailed understanding of user attitudes toward proposed features.
Feature preference rankings, highlighting the relative importance of features to the target audience.

Contextualized user quotes, offering realistic and relatable insights to guide product ideation and prototyping.

In accordance with the exemplary embodiment, the ideation module 214 process inputs from the synthesis module 212 to generate design requirements. The requirements encompass functional, aesthetic, and user experience aspects to guide the development of the proposed product.

In one or more embodiments, the functional requirements are parametrized specifications that define the core features and capabilities of the product. Examples of functional requirements include:
Heart rate monitoring, ensuring accurate and real-time health data tracking.
Water resistance, providing durability for use in various environments.
Customizable wristbands, allowing users to personalize their product experience.
Fitness tracking, delivering detailed insights into physical activity.
Seamless smartphone integration, enabling effortless synchronization across devices.

In one or more embodiments, the aesthetic requirements define quantified design parameters to align the product's appearance with user expectations. Examples include:
Sleek, minimalistic design, appealing to users who value simplicity and elegance.
Lightweight construction, ensuring comfort during extended use.
Modern, premium aesthetic, targeting tech-savvy young professionals seeking visually appealing products.
In one or more embodiments, the design requirements include user experience

(UX) considerations, represented through measurable interaction metrics to optimize user satisfaction and engagement. These considerations include:
Response time thresholds, ensuring smooth and responsive interactions.
Gesture recognition parameters, facilitating intuitive control of the product.
Navigation flow complexity scores, minimizing user effort and improving accessibility.

In one or more embodiments, the design module 216 is configured to generate and refine feature ideas for the product-to-be based on the ideation method selected by the user. The design module 216 provides multiple structured approaches, enabling users to explore and develop innovative features for the product.

In one or more embodiments, the ideation module 214 supports a Free flow Brainstorming method. This method allows the user to generate feature ideas by asking pointed questions and receiving corresponding responses. For example, if the product-to-be is a wellness application, the ideation module 214 may suggest features such as:
Daily wellness challenges, which can be personalized, themed, or community based.
Virtual group workouts and challenges, offering live feedback or class recordings.
Leaderboards and achievement badges, including options for customized or private leaderboards.

In another embodiment, the ideation module 214 supports a SCAMPER method, guiding users to explore new feature ideas by substituting, combining, adapting, modifying, putting to other uses, eliminating, or rearranging known aspects of the product-to-be. For example:
Substitute: Replace fitness tracker integration with advanced biometric tracking features for monitoring heart rate variability, stress levels, and sleep patterns.
Combine: Integrate nutritional guidance with fitness plans to create a holistic daily wellness routine, dynamically adjusting based on user feedback.
Adapt: Enhance community forums with gamification elements, encouraging active participation through rewards or badges.
Modify: Strengthen the platform's community focus by enabling sub-communities or interest-based groups that connect users over shared wellness goals.

In one or more embodiments, the ideation module 214 utilizes LLMs to analyze user inputs and recommend features or modifications tailored to the user's goals. The ideation module 214 further supports dynamic ideation by adapting its recommendations based on prior user feedback and system 102 generated insights.

In an exemplary embodiment, the design module 216 is configured to integrate design knowledge by reflecting best practices and validated design principles derived from prior successful holistic health web application designs with wearable integration.

The design module 216 provides wireframe templates that visually represent the user interface (UI) of the web application. These wireframe templates include key screens, such as the home screen, community forum, user dashboards, and other important navigation components.

The design module 216 generates wireframe templates that integrate core functional components, including form fields, dashboard elements, and tracking elements. These components are structured within a compact and user-friendly form factor, enhancing usability and engagement across different device platforms.

The design module 216 incorporates a feature list into the wireframe templates. This feature list is derived from the design module 216 and includes operational features such as AI-powered customized fitness plans, on-demand content, and daily wellness challenges designed to engage users effectively.

The design module 216 includes user stories for various roles involved in the product-to-be, such as end users, health coaches, and community moderators. These user stories specify the following:
The role and desired action (e.g., “As an end user, I want to register an account to access personalized wellness plans and track my progress”).
Prerequisites for successful task completion (e.g., the user must have an email address or social media account to sign up).
Potential error scenarios that may hinder successful task completion (e.g., incorrect email format or insufficient password strength).

In accordance with the exemplary embodiment, the go-to-market module 218 generates a detailed target market positioning report. This report emphasizes the product's premium nature, highlighting its appeal to tech-savvy fitness enthusiasts and positioning it as a high-value offering in the fitness and wellness sector.

In one or more embodiments, the go-to-market module 218 recommends a comprehensive marketing campaign plan, which includes several key strategies:

Suggested campaigns focusing on the webapp's fitness tracking capabilities and its seamless integration with wearables, aiming to highlight its unique selling points.

Recommendations for social media influencer partnerships, specifically with fitness experts, to enhance the credibility and visibility of the webapp within the target market.

A launch event plan targeting professionals and influencers in the tech and fitness industries to generate buzz and encourage early adoption.

In one or more embodiments, the go-to-market module 218 provides a sales strategy that includes:

Pre-order promotions offering limited-edition bands or other exclusive features to incentivize early adopters and drive initial sales.

Product bundling strategies that pair the webapp with accessories, such as custom bands or chargers, to enhance the perceived value and encourage higher sales volumes.

In one or more embodiments, the go-to-market module 218 provides recommendations for distribution channels. These include direct-to-consumer sales through the brand's website and strategic partnerships with fitness retailers to expand the product's reach and accessibility.

In one or more embodiments, the go-to-market module 218 also outlines performance metrics to measure the effectiveness of the proposed strategies. These include key performance indicators (KPIs) such as expected conversion rates, customer acquisition costs, and social media engagement, which are used to track the success of the market entry and growth phases.

In one or more embodiments, the system 102 aggregates all module outputs into a comprehensive data package. This data package includes the following:

Wireframe template recommendations, user interface elements, and final design features: The system 102 compiles a set of wireframe template recommendations, including user interface elements and final design features, which are tailored to the product's specifications. These templates and design elements reflect the outcomes of the design module 216 and serve as a foundation for the final user interface design.

The system 102 consolidates market research insights, synthetic user data, and competitive analysis that is generated, which includes detailed user personas, market trends, and competitor assessments to inform the product development and positioning strategy.

The system 102 integrates optimization and testing feedback from various modules, ensuring that the design is refined for user satisfaction and usability. This includes interaction metrics, UX considerations, and design adjustments based on performance testing, guaranteeing that the final product is user-friendly and meets the intended design goals.

The system 102 compiles a complete go-to-market strategy, as generated by the go-to-market module 218. This strategy includes detailed marketing campaigns, product positioning, sales strategies, and recommended distribution channels, ensuring a well-rounded and actionable approach to product launch and growth.

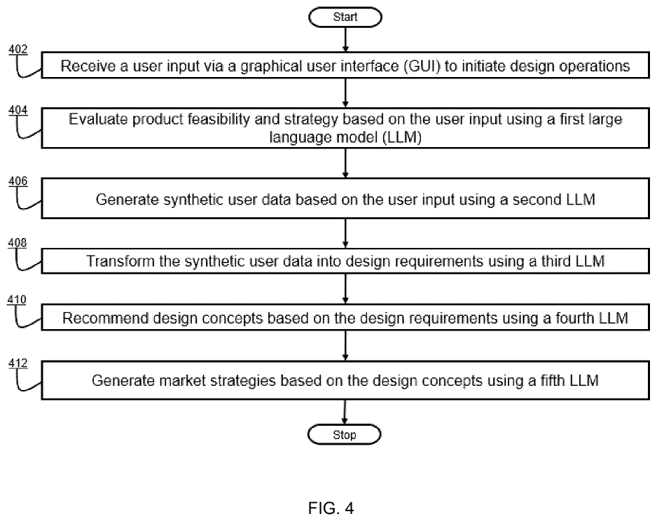

FIG. 4 is a diagram that illustrates a flow chart 400 for a method for automated design recommendation using a unified design framework, in accordance with an embodiment of the disclosure.

At 402, a user input is received via the GUI 104 to initiate design operations. The GUI 104 is also designed to receive inputs of various types, allowing for flexible and adaptable user interactions.

At 404, product feasibility and strategy are evaluated using the research and strategy module 210 based on the user input. For instance, the user input may be feasibility pitch for the product. Further, the user input may comprise target group parameters comprising demographic characteristics, behavioral patterns, and user preferences. Furthermore, the user input may comprise product details comprising product name, product objectives, market positioning, and functional requirements.

In one or more embodiments, the research and strategy module 210 is configured to evaluate the feasibility and strategy of a proposed product or service based on the user input. The research and strategy module 210 may employ various analytical techniques and scoring mechanisms to provide insights into the feasibility and strategic direction of the product.

In one or more embodiments, the research and strategy module 210 utilizes a first LLM to analyze the user input and evaluate the feasibility and strategy of the proposed product. The first LLM is configured with parameters to evaluate product feasibility and strategy based on the user input. The first LLM is pre-trained on a corpus of domain-specific and general knowledge, enabling it to perform context-aware evaluations of user inputs. The evaluation involves assessing the alignment of the proposed product or service with market trends, user needs, and strategic objectives. By employing advanced natural language understanding and reasoning capabilities, the first LLM may also examine factors such as potential demand, competitive landscape, and resource availability.

In some non-limiting embodiments, the research and strategy module 210 identifies possible constraints or risks, ensuring that the product or service aligns with the user's intended objectives. Configured with customizable parameters, the first LLM tailors its analysis to the specific requirements of the domain, thereby offering precise and actionable insights for validating product feasibility and developing robust strategies.

At 406, synthetic user data is generated by the synthesis module 212 based on the user input. The synthesis module 212 interprets the user's input to create the synthetic user data that reflects the intended user demographics or market segment, forming a robust foundation for subsequent design phases. The synthetic user data generated by the synthesis module 212 may include a wide range of user-centric insights designed to inform and guide the subsequent stages of the design cycle. The synthetic user data may include, but not limited to, simulated demographic profiles, user preferences, behavior patterns, and usage scenarios that align with the target audience specified by the user. For instance, the synthetic user data may include predictive insights, such as anticipated trends or emerging behaviors within the specified demographic.

In one or more embodiments, the synthesis module 212 may be configured to utilize a second LLM to generate synthetic user data based on the user input. The second LLM is configured with parameters for synthetic user data generation, and user behavior simulation, allowing it to create realistic, contextually relevant data that reflects the characteristics and preferences of the intended user demographic. By incorporating a range of inputs such as demographic details, behavioral patterns, and user preferences, the second LLM can simulate a diverse set of user profiles and behaviors.

In one or more embodiments, the synthesis module 212 may be further configured to simulate user interviews, analyze user behavior patterns, and produce market insights based on the simulated data. By leveraging the second LLM and advanced data generation techniques, the synthesis module 212 may be configured to create realistic interview scenarios that reflect diverse user perspectives, preferences, and needs.

At 408, the synthetic user data is transformed into design requirements by the ideation module 214. The ideation module 214 may be configured to covert the synthetic data into design requirements that can be used in subsequent phases of the design cycle. For instance, the requirements may include, but are not limited to, functional specifications, user interface guidelines, and other design parameters that directly inform the creation of design concepts and prototypes.

In one or more embodiments, the ideation module 214, by utilizing the third LLM, transforms the synthetic data into the design requirements. The third LLM is configured with parameters for transforming the synthetic data into design requirements, enabling it to analyze the synthetic data generated by the synthesis module 212 and identify key trends, user needs, and design opportunities. Through advanced machine learning algorithms, the third LLM may detect patterns within the data, such as recurring user preferences or common behavior traits, and extract relevant design requirements from these patterns.

In one or more embodiments, the ideation module 214 may also be configured to analyze unstructured data from the synthetic user data. The unstructured data may include, but not limited to, free-text responses, user comments, feedback, or other narrative forms of information that are not organized in predefined formats. By utilizing NLP and advanced machine learning techniques, the ideation module 214 may be configured to extract meaningful insights and patterns from this unstructured data. The analysis may involve, but may not be limited to identifying key themes, sentiments, or user concerns that are relevant to the design requirements, which might not be immediately apparent in structured datasets. By incorporating both structured and unstructured data, the ideation module 214 may be configured to ensure a comprehensive understanding of user needs, leading to more nuanced and informed design requirements that reflect the complexities of real-world user behavior and preferences.

In one or more embodiments, the ideation module 214 may also be configured to identify design patterns and user needs. By analyzing both structured and unstructured data from the synthetic user data, the ideation module 214 may be configured to detect recurring themes, preferences, and behaviors that inform the design process, which may include recognizing common design patterns, such as user interface preferences, interaction flows, or functionality requirements, as well as identifying specific user needs that must be addressed in the design.

In one or more embodiments, the ideation module 214 is also configured to generate structured design requirements. After analyzing the synthetic user data and identifying relevant patterns, user needs, and design opportunities, the ideation module 214 may be configured to organize these insights into a clear, structured format that can be directly applied to subsequent design phases. The structured format may include categories such as, but not limited to, functional specifications, usability criteria, interaction design principles, and performance requirements, ensuring that all design considerations are well-defined and easy to interpret.

At 410, design concepts are recommended by the design module 216 based on the design requirements. Once the ideation module 214 has transformed the synthetic user data into structured design requirements, the design module 216 may be configured to take these inputs to create innovative and practical design concepts. The process may involve exploring a range of potential solutions, brainstorming ideas, and leveraging creative algorithms to generate a variety of design alternatives that align with the identified user needs and design goals.

In one or more embodiments, the design module 216 may be configured to utilize the fourth LLM to generate design concepts based on the design requirements. The fourth LLM is specifically configured with parameters for concept generation and feasibility analysis, enabling it to produce innovative design ideas that not only align with the user's specified requirements but also consider the practicality and viability of each concept.

In some non-limiting embodiments, through its advanced algorithms, the fourth LLM explores a wide range of creative possibilities, ensuring that the generated concepts are both novel and realistic, taking into account constraints such as functionality, user experience, and technical feasibility. By leveraging the fourth LLM, the design module 216 may be configured to help streamline the creative process, providing the user with a selection of well-structured, feasible design concepts that can be further refined and developed in subsequent stages of the design cycle.

In one or more embodiments, the design module 216 includes a design knowledge base storing extracted design principles from prior implementations. The knowledge base serves as a repository of best practices, design patterns, and insights gleaned from previous projects, allowing the design module 216 to leverage this accumulated knowledge to guide generation of new prototypes.

In some non-limiting embodiments, the design knowledge base is configured to store and categorize design patterns based on implementation context, which allows the design module 216 to select and apply the most relevant design patterns depending on the specific requirements and constraints of the project, such as, but not limited to, the target user group, industry standards, or platform specifications. By organizing design patterns in this manner, the knowledge base enables more efficient decision-making and ensures that the design process leverages the most appropriate solutions for each unique context. For example, patterns for mobile app interfaces may be categorized separately from those for web applications or enterprise software, allowing the design module 216 to quickly access the right resources based on the project's needs, resulting in more relevant and effective prototypes.

In some non-limiting embodiments, the design knowledge base is configured to maintain quality standards across design iterations. This functionality ensures that, as the design evolves through multiple iterations, it consistently adheres to predefined quality benchmarks such as usability, accessibility, responsiveness, and visual consistency. By tracking and referencing these standards, the knowledge base acts as a safeguard, helping to preserve the integrity of the design throughout the development process. As design concepts are refined or modified, the knowledge base provides a reference for maintaining high-quality user experiences, preventing deviations from established best practices, and ensuring that the final prototype meets both functional and aesthetic criteria.

In some non-limiting embodiments, the design knowledge base is configured to update automatically based on validated design outcomes. As design iterations progress and real-world testing or user feedback is collected, the knowledge base is dynamically updated with new insights, patterns, and design solutions that have proven successful. This ensures that the knowledge base remains current and reflective of the latest design trends, user preferences, and industry standards. By incorporating validated outcomes, the design knowledge base continually evolves, offering more accurate and reliable references for future design projects.

In one or more embodiments, the design module 216 includes a component repository containing white-labeled design elements and reusable templates. The repository serves as a collection of pre-designed components, such as buttons, navigation bars, forms, icons, and other UI elements, which can be easily integrated into the prototype. The components are white labeled, meaning they are customizable and can be tailored to match the specific branding and visual identity of the project. Additionally, the repository includes reusable templates that provide structured layouts for common design patterns, helping to streamline the design process and maintain consistency across the prototype.

In one or more embodiments, the design module 216 may be configured to enable automated extraction and white labeling of design components. This capability allows the design module 216 to identify reusable design elements from existing prototypes, templates, or design patterns, and adapt them for new projects by removing brand-specific attributes. The extracted components, such as buttons, forms, icons, or navigation menus, are then customized to align with the visual identity and functional requirements of the current project.

In one or more embodiments, the design module 216 may be configured to enable automated application of design principles from the knowledge base. By leveraging stored principles such as usability guidelines, aesthetic standards, accessibility requirements, and industry best practices, the design module 216 may be configured to ensure that these principles are seamlessly integrated into the design process. This automation allows the design module 216 to evaluate design components and layouts in real time, applying appropriate adjustments to align with the established principles. For instance, the design module 216 may be configured to automatically optimize color contrast for accessibility, adjust spacing for visual balance, or enhance navigation flows for improved usability.

At 412, market strategies are generated by the go-to-market module 218 based on the design concepts. The go-to-market module 218 may be configured to analyze the design concepts in the context of target demographics, industry trends, and competitive landscapes to develop comprehensive strategies for successful market entry. The go-to-market module 218 may be configured to consider factors such as positioning, pricing, promotional tactics, and distribution channels to create actionable plans tailored to the product's unique attributes.

In one or more embodiments, the go-to-market module 218 may be configured to utilize a fifth LLM to generate the market strategies. The fifth LLM is configured with parameters for marketing content generation and campaign strategy development, enabling it to craft detailed and targeted approaches for product promotion and distribution. By analyzing data from validated prototypes, user demographics, market trends, and competitor benchmarks, the fifth LLM generates tailored strategies, including messaging frameworks, branding guidelines, and promotional tactics.

In one or more embodiments, the go-to-market module 218 may be configured to receive brand specifications, target audience parameters, and market requirements. In one or more embodiments, the go-to-market module 218 may be configured to receive brand specifications, target audience parameters, and market requirements. The inputs allow the go-to-market module 218 to tailor the market strategy to align with the product's branding and the specific needs of the target audience. Brand specifications may include elements such as, but not limited to, brand identity, values, and messaging tone, while target audience parameters encompass demographic data, user preferences, and behavioral insights. Market requirements may involve factors such as, but not limited to, competitive positioning, pricing strategies, and industry trends.

In one or more embodiments, the go-to-market module 218 may be configured to analyze market positioning opportunities. In one or more embodiments, the go-to-market module 218 may be configured to analyze market positioning opportunities. This functionality allows the go-to-market module 218 to assess the product's potential within various market segments, identifying areas where it can differentiate itself from competitors and capture value.

In one or more embodiments, the go-to-market module 218 is configured to generate user acquisition strategies. The feature allows the go-to-market module 218 to develop targeted plans for attracting and converting potential customers based on insights from the validated prototypes, market analysis, and audience parameters. By leveraging data on user demographics, preferences, and behaviors, the go-to-market module 218 may be configured to formulate strategies that include optimized digital marketing campaigns, influencer partnerships, referral programs, and content marketing tactics. The strategies are designed to engage the right users at the right time, driving user adoption and building brand loyalty from the outset.

In one or more embodiments, the go-to-market module 218 may be further configured to analyze market trends using the synthetic user data. By leveraging the insights derived from the synthetic data generated during the research phase, the go-to-market module 218 may be configured to identify emerging trends, shifts in consumer behavior, and evolving market demands. The analysis enables the go-to-market module 218 to refine the product's positioning, adjust its marketing strategies, and anticipate potential opportunities or threats in the market.

In one or more embodiments, the go-to-market module 218 may be further configured to recommend channel-specific marketing strategies. The functionality enables the go-to-market module 218 to tailor marketing tactics to different platforms and distribution channels, ensuring that each channel is leveraged effectively to reach the target audience. By analyzing user behavior, market trends, and platform-specific dynamics, the go-to-market module 218 may be configured to suggest optimal strategies for various channels such as social media, email marketing, search engine advertising, content marketing, and influencer partnerships.

In one or more embodiments, the go-to-market module 218 may be further configured to generate performance metrics for proposed strategies. The feature allows the go-to-market module 218 to evaluate and quantify the potential effectiveness of the suggested marketing strategies before they are implemented. By using historical data, synthetic user data, and predictive models, the go-to-market module 218 may be configured to generate key performance indicators (KPIs) such as customer acquisition cost, conversion rates, user engagement levels, and return on investment (ROI) for each proposed strategy. The metrics enable stakeholders to assess the viability of different strategies, make data-driven decisions, and optimize marketing efforts for maximum impact.

In one or more embodiments, the method further comprises creating interactive prototypes based on the design concepts generated by the design module 216. Specifically, the system 102 leverages the capabilities of LLM to transform the design concepts into detailed prototype representations. The interactive prototypes incorporate dynamic elements such as user interface behaviors, animations, and functional workflows, enabling users to experience and evaluate the proposed designs in a simulated environment. The system 102 ensures that these prototypes closely align with the design requirements established in earlier stages, facilitating iterative refinement based on user feedback or additional inputs. By offering interactive prototypes, the system 102 bridges the gap between abstract design concepts and tangible implementations, supporting comprehensive validation of usability, functionality, and overall user experience before proceeding to production stages.

In some non-limiting embodiments, the system 102 may comprise a testing module that is also configured to validate the interactive prototypes. The testing module may comprise suitable logic, code, and/or interfaces that may be configured to evaluate the prototypes against predefined usability criteria, functional requirements, and design principles to ensure their effectiveness and reliability. By leveraging advanced algorithms and integrated tools, the testing module may be configured to simulate real-world scenarios, conduct performance assessments, and identify potential usability issues.

In some non-limiting embodiments, the testing module may be configured to utilize a sixth LLM to validate the interactive prototypes and designs. The sixth LLM is configured with parameters for validation and optimization assessment, enabling it to analyze the prototypes for compliance with usability standards, functionality, and performance metrics. By evaluating aspects such as user interaction flows, accessibility, responsiveness, and visual coherence, the sixth LLM identifies areas of improvement and potential issues. Additionally, the sixth LLM provides optimization recommendations to enhance prototype quality, ensuring that the designs align with both user expectations and project objectives.

The method and system is advantageous over existing art in that it implements a unified design framework integrating multiple large language models across different design phases. This integration enables automated data transformation between phases while preserving contextual information, significantly reducing processing time and computational overhead. The system's modular architecture allows independent access to any design phase while maintaining data consistency, eliminating the technical complexities traditionally associated with multi-phase design operations.

The method and system offers a significant advantage over standalone AI tools by providing an integrated framework for the entire design process. While conventional AI tools are often specialized for individual tasks such as research (e.g., gathering user data), synthesis (e.g., creating personas), or ideation (e.g., generating concepts), these tools typically operate in isolation, making it challenging to transfer insights seamlessly between tasks. Each tool tends to focus on a narrow part of the process, and the lack of connectivity between them can result in fragmented outcomes, leaving gaps in the overall design strategy. The method and system overcomes this limitation by enabling different phases of the design process to work together in an interconnected manner. This seamless integration allows insights and data generated in one phase to directly inform and enhance subsequent phases. For example, findings from the research phase can automatically influence the synthesis phase, where personas are created, and further shape ideation, where new design concepts are generated. Additionally, insights derived from the prototyping phase can be fed back into the research phase to refine assumptions, improving the overall design process with iterative feedback loops.

The method and system leverages a design-thinking framework that incorporates contextual relevance at every step. For instance, it ensures that user research is continuously aligned with the problem space, guiding ideation in a manner that remains focused on the project's overarching goals and constraints. By maintaining a broader contextual perspective, the method and system prevents the development of siloed or disjointed results that can occur when independent tools are used in isolation. This holistic approach ensures that every phase of the design process is purposefully aligned with the project's objectives, ultimately producing more effective, coherent, and contextually relevant outcomes.

Standalone tools, while efficient at specific tasks, often lack the capacity to synthesize data in a way that provides actionable insights across different phases of the design process. For instance, while a tool may gather user data, it might not offer guidance on how that data should influence future design decisions. The method and system distinguish themselves by leveraging advanced AI to synthesize data from multiple sources—including user feedback, analytics, competitive research, and usability testing—into comprehensive insights. These insights are not isolated to a particular phase but are applicable across the entire design lifecycle, helping teams refine their design directions based on real, actionable information. By offering intelligent, data-driven recommendations, the method and system ensure that every design decision is informed by a holistic view of user needs and market trends.

Using multiple standalone AI tools often results in inefficiencies as teams struggle to manually transfer data between systems or reconcile conflicting outputs. For instance, one tool might generate a report that needs to be manually adjusted to fit the parameters of another tool, leading to unnecessary delays and increased project costs. The method and system streamline this process by automating many of these tasks, such as organizing research data, tracking design iterations, and updating user feedback. With these repetitive administrative tasks handled by AI, teams can dedicate more time to high-value activities like strategic decision-making and creative problem-solving. This automation reduces friction, accelerates workflows, and ultimately results in faster turnaround times and more efficient use of resources.

Furthermore, the method and system is advantageous in that it implements advanced data processing techniques that automatically transform outputs into domain-specific formats. This technical capability is achieved through specialized large language models configured with phase-specific parameters and domain-specific instructions, enabling automatic format conversion and terminology adaptation. The automated data transformation reduces manual intervention and potential errors in data interpretation.

Additionally, the method and system is advantageous in that it incorporates predictive analytics through specialized large language models that process synthetic user data. This implementation enables automated pattern recognition, trend analysis, and data-driven recommendations. The ability to generate and analyze synthetic data provides comprehensive insights while reducing dependency on extensive real-world data collection, thereby improving computational efficiency and reducing processing time.

Moreover, the method and system is advantageous in that it achieves technical efficiency through automated coordination between multiple design modules. The integration controller 208 manages data dependencies and maintains context across module transitions, enabling seamless data flow without manual intervention. This technical implementation eliminates data inconsistencies and reduces system resource utilization typically associated with multiple independent tools.

Furthermore, the method and system is advantageous in that its technical framework enables dynamic adaptation through real-time feedback processing and automated output refinement. Each module utilizes specialized large language models configured for specific operations, enabling automated generation and validation of outputs. This technical implementation reduces computational complexity while maintaining output quality and consistency across all design phases.

Those skilled in the art will realize that the above-recognized advantages and other advantages described herein are merely exemplary and are not meant to be a complete rendering of all of the advantages of the various embodiments of the present disclosure.

In the foregoing complete specification, specific embodiments of the present disclosure have been described. However, one of ordinary skill in the art appreciates that various modifications and changes can be made without departing from the scope of the present disclosure. Accordingly, the specification and figures are to be regarded in an illustrative rather than a restrictive sense. All such modifications are intended to be included within the scope of the present disclosure.

What is claimed is:

1. A system for automated design recommendation, comprising:
a processor; and
a memory storing instructions that, when executed by the processor, configure the system to implement:
a unified design framework, wherein the unified design framework comprises:
a graphical user interface (GUI) configured to receive a user input and present an output;
an integration controller configured to coordinate data transfers between a plurality of design modules, wherein the plurality of design modules comprising:
a research and strategy module utilizing a first large language model (LLM) to evaluate product feasibility and strategy based on the user input;
a synthesis module utilizing a second LLM to generate synthetic user data based on the user input;
an ideation module utilizing a third LLM to transform the synthetic user data into design requirements;
a design module utilizing a fourth LLM to create design concepts based on the design requirements; and
a go-to-market module utilizing a fifth LLM to generate market strategies based on design concepts.

2. The system of claim 1, wherein the user input comprises:
brand specifications comprising brand values, brand positioning, brand identity elements, and visual preferences; target group parameters comprising demographic characteristics, behavioral patterns, and user preferences; and product details comprising product name, product objectives, market positioning, and functional requirements.

3. The system of claim 1, wherein the GUI is further configured to:
enable independent access to each module of the plurality of design modules;
display module-specific input interfaces; and
present real-time updates of operations from each accessed module.

4. The system of claim 1, wherein each module of the plurality of design modules is configured to:
present intermediate outputs for user review;
receive user feedback through the GUI;
refine the outputs using the respective LLM based on the user feedback; and
proceed to subsequent operations upon user confirmation.

5. The system of claim 1, wherein the integration controller is further configured to:
maintain design context across module transitions;
track data dependencies between modules; and
enable automated data flow between consecutive modules.

6. The system of claim 1, wherein each LLM is configured through training with design-specific data comprising documented design processes, user research outcomes, design patterns, validated design solutions, integration with domain-specific instructions, and implementation of design-focused response parameters.

7. The system of claim 1, wherein the first LLM is configured with parameters to evaluate product feasibility and strategy based on the user input, the second LLM is configured with parameters for synthetic data generation based on the user input, the third LLM is configured with parameters to transform the synthetic user data into design requirements, the fourth LLM is configured with parameters to create design concepts based on the design requirements, and the fifth LLM is configured with parameters for marketing strategies generation and campaign strategy development.

8. The system of claim 7, wherein each LLM implements module-specific input processing rules, customized response generation parameters, and output validation criteria aligned with the respective module's objectives.

9. The system of claim 1, wherein the ideation module is further configured to:
analyze unstructured data from the synthetic user data;
identify design patterns and user needs; and
generate structured design requirements.

10. The system of claim 1, wherein the ideation module is configured to:
present multiple ideation methodologies for user selection;
receive user selection of an ideation method; and
adapt the ideation process based on the selected method.

11. The system of claim 1, wherein the design module is further configured to:
generate multiple design alternatives based on the design requirements;
evaluate feasibility of each alternative; and
rank design concepts based on predefined criteria.

12. The system of claim 1, wherein the design module is further configured to:
convert design concepts into interactive wireframes; and
generate responsive prototype elements.

13. The system of claim 1, wherein the design module further comprises:
a design knowledge base storing extracted design principles from prior implementations; and
a component repository containing white-labeled design elements and reusable templates.

14. The system of claim 13, wherein the design knowledge base is configured to:
store and categorize design patterns based on implementation context;
maintain quality standards across design iterations; and
update automatically based on validated design outcomes.

15. The system of claim 1, wherein the fourth LLM is configured to:
analyze the design concepts against stored design principles;
recommend optimal component combinations; and
validate designs against established standards.

16. The system of claim 1, wherein the design module enables automated:
extraction and white labeling of design components;
application of design principles from the knowledge base; and
prototype refinement based on LLM recommendations.

17. The system of claim 1 further comprises a testing module utilizing a sixth LLM to validate interactive prototypes and designs, wherein the testing module is further configured to:
simulate user testing scenarios;
analyze interaction patterns; and
generate optimization recommendations.

18. The system of claim 1, wherein the go-to-market module is configured to:
receive brand specifications, target audience parameters, and market requirements;
analyze market positioning opportunities; and
generate user acquisition strategies.

19. The system of claim 18, wherein the go-to-market module is further configured to:
analyze market trends using the synthetic user data;
recommend channel-specific marketing strategies; and
generate performance metrics for proposed strategies.

20. A computer-implemented method for automated design recommendation, comprising:
receiving, via a graphical user interface (GUI), a user input to initiate design operations;
evaluating, using a first large language model (LLM), product feasibility and strategy based on the user input;
generating, using a second LLM, synthetic user data based on the user input;
transforming, using a third LLM, the synthetic user data into design requirements;
creating, using a fourth LLM, design concepts based on the design requirements; and
generating, using a fifth LLM, market strategies based on the design concepts.

21. The method of claim 20, wherein each LLM is configured through training with design-specific data comprising documented design processes, user research outcomes, design patterns, validated design solutions, integration with domain-specific instructions, and implementation of design-focused response parameters.

22. The method of claim 20, wherein the first LLM is configured with parameters to evaluate product feasibility and strategy based on the user input, the second LLM is configured with parameters for synthetic data generation based on the user input, the third LLM is configured with parameters to transform the synthetic user data into design requirements, the fourth LLM is configured with parameters to create design concepts based on the design requirements, and the fifth LLM is configured with parameters for marketing strategies generation and campaign strategy development.

23. The method of claim 22, wherein each LLM implements module-specific input processing rules, customized response generation parameters, and output validation criteria aligned with the respective module's objectives.

24. The method of claim 20, further comprising:
analyzing unstructured data from the synthetic user data;
identifying design patterns and user needs; and
generating structured design requirements.

25. The method of claim 20, further comprising
presenting multiple ideation methodologies for user selection;
receiving user selection of an ideation method; and
adapting the ideation process based on the selected method.

26. The method of claim 20, further comprising:
generating multiple design alternatives based on the design requirements;
evaluating feasibility of each alternative; and
ranking design concepts based on predefined criteria.

27. The method of claim 20 further comprising validating interactive prototypes and designs using a testing module by:
simulating user testing scenarios;
analyzing interaction patterns; and
generating optimization recommendations.

28. The method of claim 27, wherein validating the interactive prototypes comprises:
simulating user testing scenarios;
analyzing interaction patterns;
identifying usability issues; and
generating optimization recommendations.

29. The method of claim 20, wherein generating market strategies comprises:
analyzing market positioning opportunities;
creating channel-specific marketing strategies;
generating user acquisition recommendations; and
producing performance metrics for proposed strategies.

30. The method of claim 20, further comprising:
tracking data dependencies between operations;
maintaining design context across transitions; and
enabling automated data flow between consecutive operations.

31. The method of claim 20, wherein refining outputs comprises:
analyzing user feedback;
adjusting LLM parameters based on feedback;
regenerating outputs with adjusted parameters; and
presenting updated results for user confirmation.
